(19) United States
(12) Patent Application Publication
(10) Pub. No.: US 2025/0267879 A1
(43) Pub. Date: Aug. 21, 2025

(54) MANUFACTURING METHOD OF MEMORY DEVICE

(71) Applicant: SK hynix Inc., Icheon-si Gyeonggi-do (KR)

(72) Inventor: Heon Yong CHANG, Icheon-si Gyeonggi-do (KR)

(73) Assignee: SK hynix Inc., Icheon-si Gyeonggi-do (KR)

(21) Appl. No.: 18/787,428

(22) Filed: Jul. 29, 2024

(30) Foreign Application Priority Data
Feb. 15, 2024 (KR) 10-2024-0021846

(51) Int. Cl. H10B 80/00; H01L 23/00; H01L 25/00; H01L 25/065; H01L 25/18

(52) U.S. Cl. CPC H10B 80/00; H01L 24/08; H01L 24/80; H01L 25/0657; H01L 25/18; H01L 25/50; H01L 2224/08145; H01L 2224/80031; H01L 2224/80048; H01L 2224/80895; H01L 2224/80896; H01L 2924/1431; H01L 2924/14511

(57) ABSTRACT

The present disclosure relates to a method of manufacturing a memory device. A method of manufacturing a memory device includes forming a peripheral circuit over a first substrate, forming a first source line over a second substrate, forming a memory cell array including gate lines, cell plugs extending through the gate lines, and bit lines electrically coupled to the cell plugs that protrude into the first source line, bonding the memory cell array to the peripheral circuit, and removing at least a portion of the second substrate.

### CROSS-REFERENCE TO RELATED APPLICATION

The present application claims priority under 35 U.S.C. § 119(a) to Korean patent application number 10-2024-0021846 filed on Feb. 15, 2024, in the Korean Intellectual Property Office, the entire contents of which application is incorporated herein by reference.

### BACKGROUND

### 1. Technical Field

Various embodiments of the present disclosure generally relate to a manufacturing method of a memory device, including but not limited to, a method of manufacturing a memory device using wafer bonding.

### 2. Related Art

A memory device includes a memory cell array in which data is stored and a peripheral circuit configured to perform a program, read, or erase operation of the memory cell array.

A memory cell array includes a plurality of memory blocks and the plurality of memory blocks include a plurality of memory cells that are stacked in a vertical direction above a substrate.

The number of memory cells included in the memory cell array increases as data storage capacity of the memory device increases. Therefore, a size of the memory device increases. In order to reduce the size of the memory device, the peripheral circuit and the memory cell array may be formed over different substrates. The peripheral circuit and the memory cell array formed over the different substrates are bonded to each other. This manufacturing method is referred to as wafer bonding.

As the peripheral circuit and the memory cell array are manufactured over the different substrates and bonded to each other in the wafer bonding, different materials or structural differences may cause stress or warpage in which the substrates are bent.

### SUMMARY

According to an embodiment, a manufacturing method of a memory device may include forming a peripheral circuit over a first substrate, forming a first source line over a second substrate, forming a memory cell array including gate lines, cell plugs extending through the gate lines, and bit lines electrically coupled to the cell plugs that protrude into the first source line, bonding the memory cell array to the peripheral circuit, and removing at least a portion of the second substrate.

According to an embodiment, a manufacturing method of a memory device may include forming a peripheral circuit over a first substrate, performing an ion implantation process on a second substrate, forming a memory cell array over the ion-implanted second substrate, bonding the memory cell array to the peripheral circuit, and removing a portion of the second substrate.

According to an embodiment, a manufacturing method of a memory device may include forming a peripheral circuit over a first substrate; implanting first impurities into a second substrate to form a first source line; forming a memory cell array over the second substrate such that cell plugs of the memory cell array extend into the first source line; bonding the memory cell array to the peripheral circuit; and removing at least a portion of the second substrate.

### BRIEF DESCRIPTION OF THE DRAWINGS

FIG. 1 is a diagram illustrating a memory device according to an embodiment of the present disclosure;

FIG. 2 is a diagram illustrating a memory block according to an embodiment of the present disclosure;

FIG. 3 is a diagram illustrating locations of a peripheral circuit and a memory cell array according to an embodiment of the present disclosure;

FIG. 4 is a diagram illustrating gate lines and cell plugs included in a memory block according to an embodiment of the present disclosure;

FIG. 5 is a cross-sectional view of a memory device according to an embodiment of the present disclosure;

FIG. 6A to FIG. 6E are cross-sectional views of a memory device formed utilizing a method of manufacturing the memory device according to an embodiment of the present disclosure;

FIG. 7 is a cross-sectional view of a memory device formed utilizing a method of manufacturing the memory device according to an embodiment of the present disclosure;

FIG. 8A and FIG. 8B are cross-sectional views of a memory device formed utilizing a method of manufacturing a memory device according to an embodiment of the present disclosure;

FIG. 9 is a diagram illustrating an embodiment of a memory card system including a memory device according to an embodiment of the present disclosure; and

FIG. 10 is a diagram illustrating an embodiment of a solid state drive (SSD) system including a memory device according to an embodiment of the present disclosure.

### DETAILED DESCRIPTION

Specific structural or functional descriptions disclosed below describe an embodiment according to the concepts of the present disclosure. The embodiment according to the concept of the present disclosure is not construed as limited to the embodiments described below and may be modified in various forms and replaced with other equivalent embodiments.

Terms such as “first” and “second” may be used to describe various components, but the components are not limited by the terms. The terms are used for the purpose of distinguishing one component from another component and do not imply size, order, priority, quantity, or importance of the components. When one element is identified as “coupled” to another element, the elements may be connected or coupled directly or through an intervening element between the elements. When two elements are identified as “directly coupled,” one element is directly connected or directly coupled to the other element without an intervening element between the two elements. When one element is identified as “on” or “over” another element, the elements may directly contact each other or an intervening element may be disposed between the elements. Terms such as “vertical,” “above,” “under,” “beneath,” “over,” “on,” “side,” “upper,” “lower,” “uppermost,” “lowermost,” and other terms implying relative spatial relationship or orientation are utilized only for the purpose of ease of description or reference to a drawing and are not otherwise limiting.

Various embodiments of the present disclosure are described in detail with reference to the accompanying drawings.

The cross-hatching throughout the figures illustrates corresponding or similar areas between the figures rather than indicating the materials for the areas.

Various embodiments are directed to a method of manufacturing a memory device capable of reducing warpage during wafer bonding.

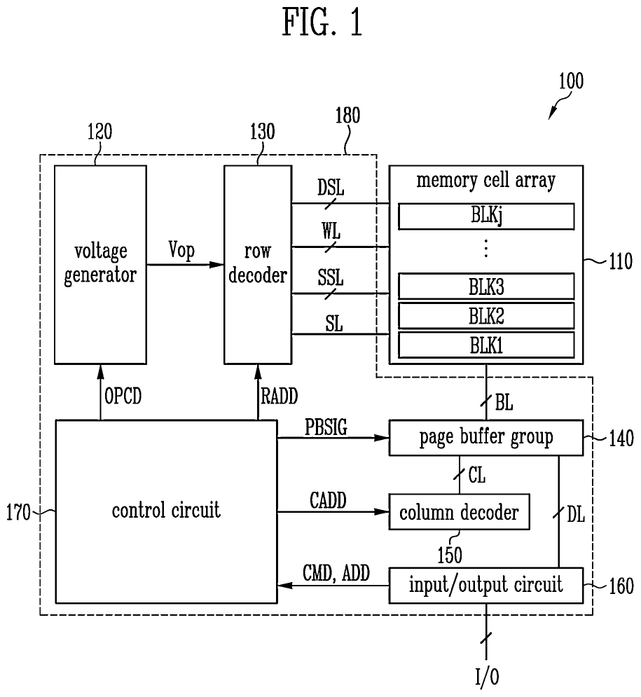

FIG. 1 is a diagram illustrating a memory device 100.

Referring to FIG. 1, the memory device 100 includes a memory cell array 110 and a peripheral circuit 180.

The memory cell array 110 includes a first memory block BLK1 to a jth memory block BLKj, where j is a positive integer. When the memory blocks BLK1 to BLKj are referenced, each of memory block BLK1, memory block BLK2, memory block BLK3, . . . , through memory block BLKn, such as memory block BLK1 through BLKj, are included. Each of the memory blocks BLK1 to BLKj includes memory cells capable of storing data. Drain select lines DSL, word lines WL, source select lines SSL, and a source line SL are coupled to each of the memory blocks BLK1 to BLKj, and bit lines BL are commonly coupled to the memory blocks BLK1 to BLKj.

The memory blocks BLK1 to BLKj have a two-dimensional structure or a three-dimensional structure. Memory blocks having a two-dimensional structure include memory cells arranged in parallel with a substrate. Memory blocks having a three-dimensional structure include memory cells stacked over the substrate, for example, in a vertical direction. In an embodiment, memory blocks having a three-dimensional structure are provided.

The memory cells may store one-bit or two or more bits of data according to a program method. For example, a method in which one-bit data is stored in one memory cell is referred to as a single level cell (SLC) method, and a method in which two-bit data is stored in one memory cells is referred to as a multi-level cell (MLC) method. A method in which three-bit data is stored in one memory cell is referred to as a triple level cell (TLC) method, and a method in which four-bit data is stored in one memory cell is referred to as a quad level cell (QLC) method.

The peripheral circuit 180 is configured to perform a program operation that stores data in the memory cell array 110, a read operation that outputs data stored in the memory cell array 110, and an erase operation that erases data stored in the memory cell array 110. For example, the peripheral circuit 180 includes a voltage generator 120, a row decoder 130, a page buffer group 140, a column decoder 150, an input/output circuit 160, and a control circuit 170.

The voltage generator 120 generates various operating voltages Vop used for any of a program operation, a read operation, and an erase operation in response to an operation code OPCD. For example, the voltage generator 120 is configured to generate program voltages, turn-on voltages, turn-off voltages, negative voltages, pre-charge voltages, verify voltages, read voltages, pass voltages, and erase voltages in response to the operation code OPCD. The operating voltages Vop generated by the voltage generator 120 are applied to the drain select lines DSL, the word lines WL, the source select lines SSL, and the source line SL of a selected memory block by the row decoder 130.

The program voltages are applied to a selected word line among the word lines WL during a program operation and are used to increase threshold voltages of memory cells coupled to the selected word line. The turn-on voltages are applied to the drain select lines DSL or the source select lines SSL and are used to turn on drain select transistors and source select transistors. The turn-off voltages are applied to the drain select lines DSL or the source select lines SSL and are used to turn off the drain select transistors and the source select transistors. For example, the turn-off voltages may be OV. The pre-charge voltages may be higher than OV and are applied to the bit lines during a read operation. The verify voltages are used during a verify operation that determines whether threshold voltages of selected memory cells are increased to a target level. The verify voltages may be set to various levels according to the target level and are applied to the selected word line.

The read voltages are applied to the selected word line during a read operation of the selected memory cells. For example, the read voltages may be set to various levels according to a program method of the selected memory cells. The pass voltages are applied to unselected word lines among the word lines WL during a program operation or a read operation and are used to turn on memory cells coupled to the unselected word lines.

The erase voltages are used during an erase operation that erases the memory cells included in the selected memory block and are applied to the source line SL.

The row decoder 130 is configured to transfer the operating voltages Vop to the drain select lines DSL, the word lines WL, the source select lines SSL, and the source line SL, each of which is coupled to the selected memory block according to a row address RADD. For example, the row decoder 130 is coupled to the voltage generator 120 through global lines and is coupled to the memory blocks BLK1 to BLKj through the drain select lines DSL, the word lines WL, the source select lines SSL, and the source line SL.

The page buffer group 140 includes a plurality (j) of page buffers (not shown) respectively coupled to the memory blocks BLK1 to BLKj. Each of the page buffers is coupled to the memory blocks BLK1 to BLKj through the corresponding bit lines BL. During a read operation, the page buffers, in response to page buffer control signals PBSIG, sense a current or a voltage of the bit lines BL, which current or voltage varies according to the threshold voltages of the selected memory cells and temporarily stores sensed data.

The column decoder 150 is configured to facilitate transfer of data between the page buffer group 140 and the input/output circuit 160 in response to a column address CADD. For example, the column decoder 150 is coupled to the page buffer group 140 through column lines CL and transfers enable signals through the column lines CL. The page buffers included in the page buffer group 140 receive or output data through data lines DL in response to the enable signals.

The input/output circuit 160 is configured to receive or output a command CMD, an address ADD, or data through input/output lines I/O. For example, the input/output circuit 160 transfers the command CMD and the address ADD, received from an external controller, to the control circuit 170 through the input/output lines I/O and transfers data received from the external controller to the page buffer group 140 through the input/output lines I/O. Alternatively, the input/output circuit 160 outputs data DATA transferred from the page buffer group 140 to the external controller through the input/output lines I/O.

The control circuit 170 outputs the column address CADD in response to the command CMD and the address ADD. For example, when the command CMD input to the control circuit 170 corresponds to a program operation, the control circuit 170 controls the peripheral circuit 180 to perform the program operation on a memory block selected by the address ADD. When the command CMD input to the control circuit 170 corresponds to a read operation, the control circuit 170 controls devices included in the peripheral circuit 180 to perform the read operation on the memory block selected by the address ADD and output read data. When the command CMD input to the control circuit 170 corresponds to an erase operation, the control circuit 170 controls devices included in the peripheral circuit 180 to perform the erase operation on the selected memory block.

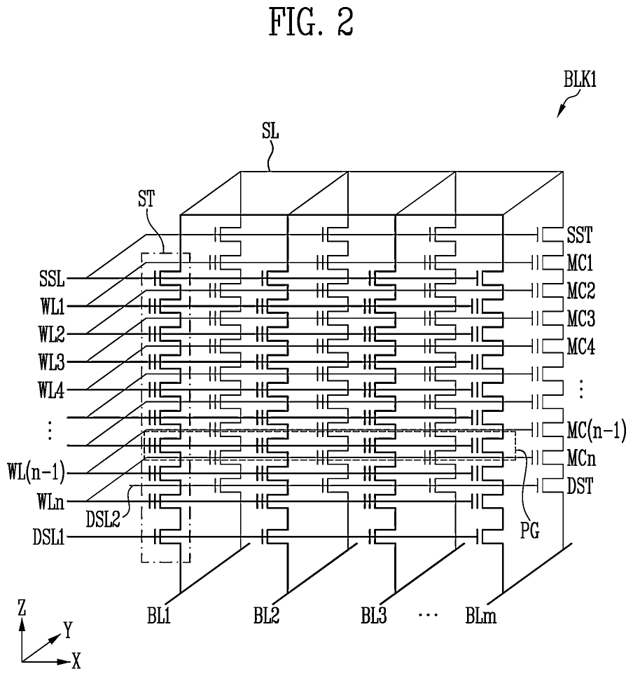

FIG. 2 is a diagram illustrating the first memory block BLK1.

Referring to FIG. 2, the first memory block BLK1 is presented as an example of one of the memory blocks BLK1 to BLKj.

The first memory block BLK1 includes a plurality of cell strings ST that are coupled between the source line SL and a first bit line BL1 to an mth bit lines BLm, where m is a positive integer. The cell strings ST are commonly coupled to the source line SL. Some of the cell strings ST are coupled to the bit lines BL1 to BLm and other cell strings ST are coupled to the same bit line among the bit lines BL1 to BLm. For example, the cell strings ST arranged in an X direction may be coupled to the bit lines BL1 to BLm, and the cell strings ST arranged in a Y direction may be coupled to the same bit line.

Each of the plurality of cell strings ST includes a source select transistor SST, memory cells MC1 to MCn, where n is a positive integer, and a drain select transistor DST. Among the plurality of cell strings ST, the cell string ST coupled to the first bit line BL1 are described below as an example.

The source select transistor SST is coupled between the source line SL and the first memory cell MC1 and the drain select transistor DST is coupled between the nth memory cell MCn and the first bit line BL1. The memory cells MC1 to MCn are coupled between the source select transistor SST and the drain select transistor DST. The quantity of source select transistors SST and the quantity of drain select transistors DST are not limited to those shown in FIG. 2. In addition to the memory cells MC1 to MCn, dummy cells may be coupled between the source select transistor SST and the drain select transistor DST. The memory cells MC1 to MCn store user data or normal data, and the dummy cells store dummy data.

Gates of the source select transistor SST included in different cell strings ST are coupled to the source select line SSL. Gates of the memory cells MC1 to MCn included in different cell strings ST are coupled to word lines WL1 to WLn. Gates of the drain select transistor DST included in different cell strings ST are coupled to a first drain select line DSL1 or a second drain select line DSL2. The first and second select lines DSL1 and DSL2 are extended in the X direction and are parallel to each other in the Y direction as shown in the example of FIG. 2.

A group of memory cells that are included in the cell strings ST arranged in the X direction and coupled to the same word line are referred to as a page PG. In a memory device, program operations and read operations for the selected memory block may be performed in units of pages or on a page basis.

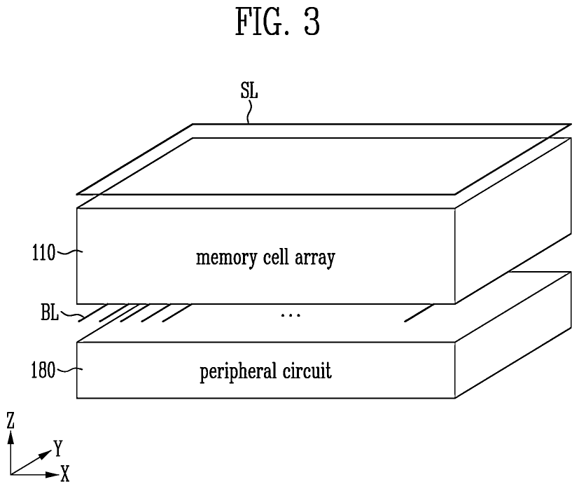

FIG. 3 is a diagram illustrating relative locations of the peripheral circuit 180 and the memory cell array 110.

Referring to FIG. 3, the memory device 100 includes the memory cell array 110 stacked over the peripheral circuit 180. The peripheral circuit 180 and the memory cell array 110 are formed independently of each other over different substrates, and the peripheral circuit 180 and the memory cell array 110 are bonded to each other by a wafer bonding process. For example, when the peripheral circuit 180 is formed over a first substrate, the memory cell array 110 is formed over a second substrate.

The bit lines BL are located between the peripheral circuit 180 and the memory cell array 110 as shown in FIG. 3. The source line SL is located over the memory cell array 110.

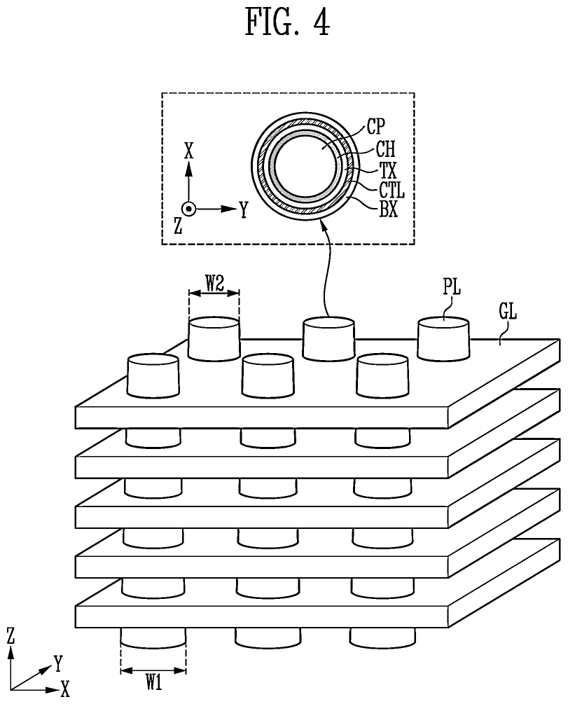

FIG. 4 is a diagram illustrating gate lines GL and cell plugs PL included in a memory block.

Referring to FIG. 4, the gate lines GL included in a memory block are stacked in a Z direction. The gate lines GL may include metallic materials such as tungsten (W), molybdenum (Mo), cobalt (Co), or nickel (Ni) or may include semiconductor materials such as silicon (Si) or polysilicon (Poly-Si). Materials of the gate lines are not necessarily limited these materials. The gate lines GL serve as a word line, a drain select line, or a source select line.

The cell plugs PL extend through the gate lines GL. For example, the cell plugs PL extend through the gate lines GL in the Z direction. Each of the cell plugs PL includes a core pillar CP, a channel layer CH, a tunnel isolation layer TX, a charge trap layer CTL, and a blocking layer BX. The core pillar CP may have a cylindrical shape, a rectangular pillar shape, or a polygonal pillar shape and may include an insulating material or an electrically conductive material. The channel layer CH surrounds a side surface of the core pillar CP and may include polysilicon. The tunnel isolation layer TX surrounds a side surface of the channel layer CH and may include an oxide layer. The charge trap layer CTL surrounds a side surface of the tunnel isolation layer TX and may include a nitride layer. The blocking layer BX surrounds a side surface of the charge trap layer CTL and may include an oxide layer.

In this embodiment, a portion of the memory cell array is formed over the substrate and flipped or rotated before performing a wafer bonding process, such that each of the cell plugs PL has a smaller upper width than a lower width relative to the orientation shown in FIG. 4. For example, the lower width of each of the cell plugs PL is a first width W1, and the upper width of each of the cell plugs PL has a second width W2 that is smaller than the first width W1. The first width W1 and the second width may be diameters of the cell plugs PL.

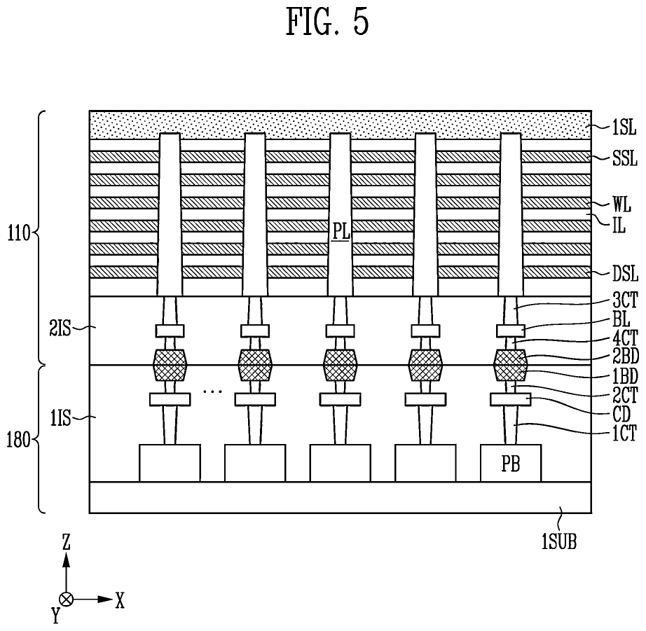

FIG. 5 is a cross-sectional view of a memory device according to an embodiment of the present disclosure.

Referring to FIG. 5, the peripheral circuit 180 includes a first substrate 1SUB and peripheral circuit elements formed over the first substrate 1SUB. For example, the peripheral circuit elements include a page buffer PB, a first contact 1CT, a contact pad CD, a second contact 2CT, and a first bonding pad 1BD. In FIG. 5, the page buffer PB is shown as an example. Circuits in addition to the circuits shown in FIG. 5 may be included in the peripheral circuit 180 of FIG. 1. For example, a plurality of transistors and a plurality of lines constituting peripheral circuits may be included in the peripheral circuit 180. Referring to the example configuration shown in FIG. 5, the page buffer PB is located over the first substrate 1SUB and the first contact 1CT is located on the page buffer PB. For example, the first contact 1CT is electrically coupled to the page buffer PB. The contact pad CD contacts the first contact 1CT, and the second contact 2CT contacts the contact pad CD, thus the first contact 1CT and the second contact 2CT are electrically coupled. The first contact 1CT, the contact pad CD, the second contact 2CT, and the first bonding pad 1BD may include an electrically conductive material. A first interlayer insulating layer 1IS fills the space between the page buffer PB, the first contact 1CT, the contact pad CD, the second contact 2CT, and the first bonding pad 1BD. The first interlayer insulating layer 1IS may include a silicon oxide layer.

The memory cell array 110 located over the peripheral circuit 180 include a first source line 1SL, the source select line SSL, the word line WL, the drain select line DSL, a plurality of insulating layers IL, a second interlayer insulating layer 2IS, a third contact 3CT, the bit line BL, a fourth contact 4CT, and a second bonding pad 2BD. For example, the second bonding pad 2BD contacts the first bonding pad 1BD of the peripheral circuit 180. The fourth contact 4CT, the bit line BL, and the third contact 3CT are sequentially stacked over or coupled to the second bonding pad 2BD and are electrically coupled through the stack. The second bonding pad 2BD, the fourth contact 4CT, the bit line BL, and the third contact 3CT include an electrically conductive material. The bonding pads 1BD and 2BD may include copper (Cu). The second interlayer insulating layer 2IS fills the space between the second bonding pad 2BD, the fourth contact 4CT, the bit line BL, and the third contact 3CT. The second interlayer insulating layer 2IS may include a silicon oxide layer.

The peripheral circuit 180 and the memory cell array 110 contact each other through the first insulating layer 1IS and the second insulating layer 2IS and the first bonding pad 1BD and the second bonding pad 2BD. For example, the second interlayer insulating layer 2IS contacts the first interlayer insulating layer 1IS, and the second bonding pad 2BD contacts the first bonding pad 1BD.

The drain select line DSL, the word line WL, and the source select line SSL are spaced apart from each other and stacked sequentially over the second interlayer insulating layer 2IS and the third contact 3CT. One of the plurality of insulating layers IL is formed between the drain select line DSL, the word lines WL, and the source select line SSL. In addition, the insulating layer IL is formed between the drain select line DSL and the second interlayer insulating layer 2IS. The drain select line DSL, the word line WL, and the source select line SSL are the gate lines GL shown in FIG. 4.

The cell plugs PL extends through the drain select line DSL, the word line WL, the source select line SSL, and the insulating layer IL to contact the third contacts 3CT. For example, the cell plug PL is formed such that the channel layer CH included in the cell plug PL as shown in FIG. 4 contacts the third contact 3CT. A portion of an upper part of the cell plug PL protrudes above or away from the insulating layer IL located over the source select line SSL.

The first source line 1SL is located over an uppermost insulating layer IL and the protruding portion of the cell plug PL. The first source line 1SL is electrically coupled to the channel layer CH of the cell plug PL. The first source line 1SL is formed by implanting impurities or ion implantation into the substrate. For example, the substrate may be a silicon substrate. The impurities implanted into the substrate to form the first source line 1SL may include N-type impurities. For example, N-type impurities may include phosphorus (P) ions or arsenic (As) ions.

The above description explains the configurations shown in FIG. 5. A plurality of configurations in addition to the example of FIG. 5 are possible.

A manufacturing method of the memory device described above with reference to FIG. 5 is described in detail.

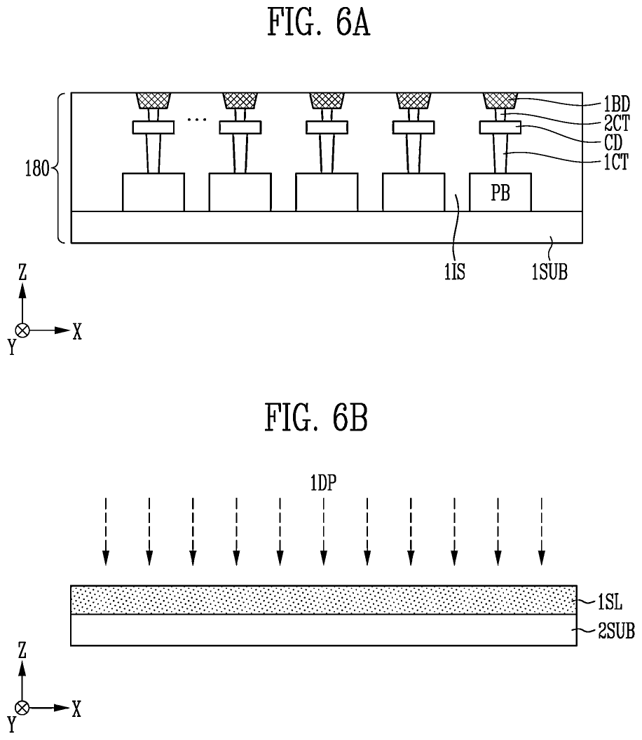

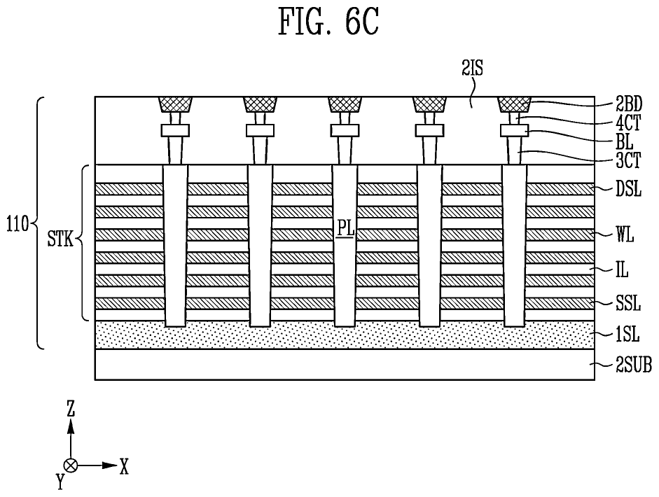

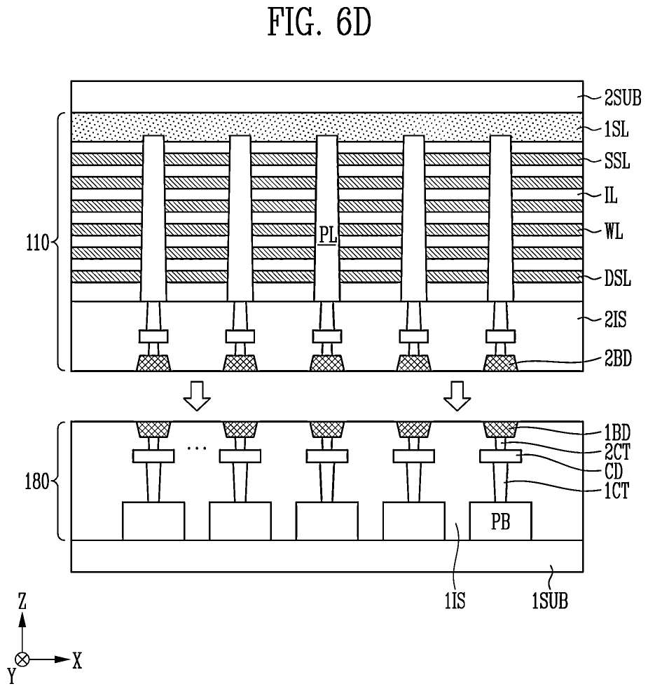

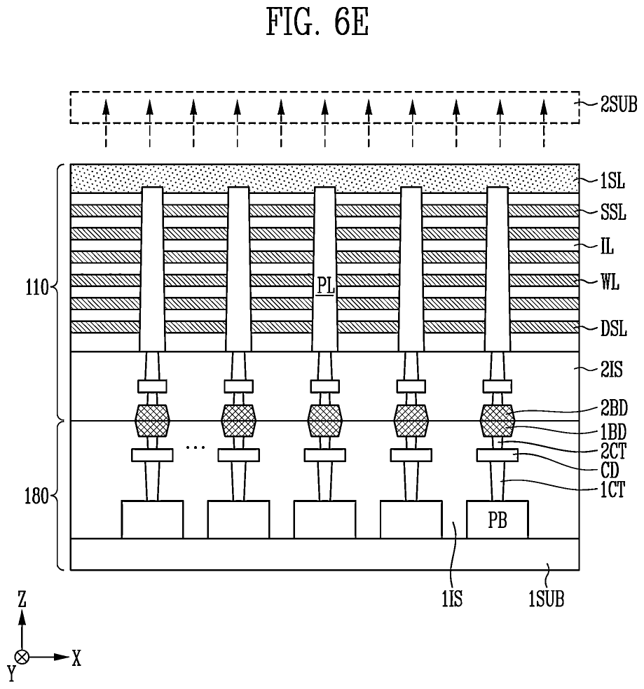

FIG. 6A to FIG. 6E are cross-sectional views of a memory device formed utilizing a method of manufacturing the memory device according to an embodiment of the present disclosure. The following describes formation of a single group of elements, although numerous similar groups of elements are formed, typically simultaneously. For example, multiple page buffers PB are formed, multiple first contacts 1CT are formed, multiple contact pads CD are formed, multiple second contacts 2CT are formed, and multiple first bonding pads 1BD are formed, and so forth.

Referring to FIG. 6A, the first interlayer insulating layer 1IS, the page buffer PB, the first contact 1CT, the contact pad CD, the second contact 2CT, and the first bonding pad 1BD are formed over the first substrate 1SUB. In addition to the page buffer PB, circuits included in the peripheral circuit 180 of FIG. 1 are formed. For example, a plurality of transistors and lines may be formed over the first substrate 1SUB. Referring to the configuration shown in FIG. 6A, the page buffer PB is formed over the first substrate 1SUB, and the first contact 1CT is formed on the page buffer PB. For example, the first contact 1CT is electrically coupled to the page buffer PB. The contact pad CD is formed on the first contact 1CT, and the second contact 2CT is formed on the contact pad CD. Each of the first contact 1CT, the contact pad CD, the second contact 2CT, and the first bonding pad 1BD include an electrically conductive material. The first interlayer insulating layer 1IS fills the space between the page buffers PB, the first contacts 1CT, the contact pads CD, the second contacts 2CT, and the first bonding pads 1BD. The first interlayer insulating layer 1IS includes a silicon oxide layer. The first interlayer insulating layer 1IS may include a plurality of insulating layers. For example, the plurality of insulating layers constituting the first interlayer insulating layer 1IS may comprise a forming layer corresponding to each of the plurality of page buffers PB, the plurality of first contacts 1CT, the plurality of contact pads CD, the plurality of second contacts 2CT, and the plurality of first bonding pads 1BD.

Referring to FIG. 6B, the first source line 1SL is formed by implanting first impurities 1DP or ion implantation into a second substrate 2SUB. The first impurities 1DP may include N-type impurities. For example, N-type impurities may include phosphorus (P) ions or arsenic (As) ions.

When the first impurities 1DP are implanted into the second substrate 2SUB, an area in which the first impurities 1DP are injected is in an amorphous state. Therefore, a heat treatment process may be performed to change the amorphous state into a crystalline state, in other words, the area including the impurities is crystallized. The heat treatment process may be performed using a laser, and various kinds of heat treatment processes may also be selectively performed.

Referring to FIG. 6C, the memory cell array 110 including a stack structure STK and the cell plugs PL is formed over the first source line 1SL. The stack structure STK includes the source select line SSL, the word line WL, the drain select line DSL, and the insulating layer IL. The cell plugs PL are formed extending through the stack structure STK into the first source line 1SL. The source select line SSL, the word line WL, and the drain select line DSL may include at least one of tungsten (W), cobalt (Co), nickel (Ni), molybdenum (Mo), silicon (Si), and polysilicon (poly-Si), and may include various conductive layers in addition to above materials. The insulating layer IL may include a silicon oxide layer.

The cell plugs PL are formed in a hole extending through the stack structure STK and contacting the first source line 1SL. The cell plugs PL include the core pillar CP, the channel layer CH, the tunnel isolation layer TX, the charge trap layer CTL, and the blocking layer BX as described with reference to FIG. 4. For example, the blocking layer BX is formed along a side or inner surface of the stack structure STK adjacent to the hole, and the charge trap layer CTL is formed along an inner surface of the blocking layer BX. The tunnel isolation layer TX is formed along an inner surface of the charge trap layer CTL, and the channel layer CH is formed along an inner surface of the tunnel isolation layer TX. The core pillar CP is formed along an inner surface of the channel layer CH. Instead of the core pillar CP, the channel layer CH may the space inside the tunnel isolation layer TX. The insulating layer IL is formed over the lowermost conductive layer SSL and uppermost conductive layer DSL of the stack structure STK.

The third contact 3CT, the bit line BL, the fourth contact 4CT, and the second bonding pad 2BD are sequentially stacked over an upper portion of the cell plug PL. The third contact 3CT, the bit line BL, the fourth contact 4CT, and the second bonding pad 2BD include an electrically conductive material. The second interlayer insulating layer 2IS fills the space between the third contact 3CT, the bit line BL, the fourth contact 4CT, and the second bonding pad 2BD. The second interlayer insulating layer 2IS may include a silicon oxide layer.

Referring to FIG. 6D, the memory cell array 110 is bonded to the peripheral circuit 180 described with reference to FIG. 6A. For example, the memory cell array 110 described with reference to FIG. 6C may be flipped or rotated, such that the second substrate 2SUB is located above the second bonding pad 2BD. Alternatively, processing may continue without flipping or rotating the structure of FIG. 6C. Subsequently, the first bonding pad 1BD of the peripheral circuit 180 is bonded to the second bonding pad 2BD of the memory cell array 110. The first interlayer insulating layer 1IS of the peripheral circuit 180 is bonded to the second interlayer insulating layer 2IS of the memory cell array 110.

Referring to FIG. 6E, an etching process is performed to remove the second substrate 2SUB that is located over the memory cell array 110 in the orientation as shown. The etching process may be performed utilizing a wet etching process or a planarization process. The planarization process may be a chemical mechanical polishing (CMP) process. During the etching process that removes the second substrate 2SUB, the CMP process and the wet etching process may be sequentially performed.

The etching process that removes the second substrate 2SUB may be performed until the first source line 1SL is exposed. The first source line 1SL that is exposed by removing the second substrate 2SUB may serve as a source line for the memory cell array 110.

When the second substrate 2SUB is removed, the first source line 1SL remains. As a result, the cell plug PL is not exposed. Because the cell plug PL is not exposed to an etchant, the cell plug PL is protected.

Because the first source line 1SL formed by implanting the first impurities 1DP into a portion of the second substrate 2SUB remains, the first source line 1SL serves as a support that protects against warpage of the memory cell array 110 during the etching process that removes the second substrate 2SUB.

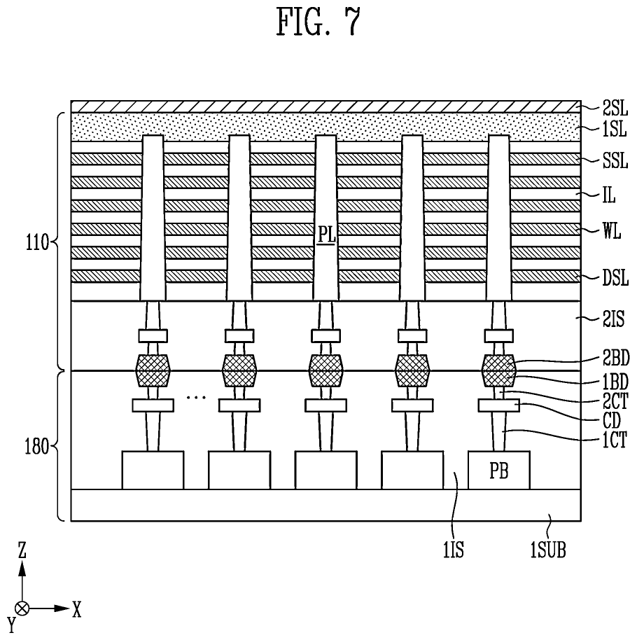

FIG. 7 is a cross-sectional view of a memory device formed utilizing a method of manufacturing the memory device according to an embodiment of the present disclosure.

Referring to FIG. 7, when the first source line 1SL is exposed by removing the second substrate 2SUB as described with reference to FIG. 6E, a second source line 2SL may be formed over the first source line 1SL to lower the resistance of the source line of the memory cell array 110. The second source line 2SL includes an electrically conductive material. For example, the second source line 2SL may include polysilicon (poly-Si).

Because the cell plug PL is not exposed when forming the second source line 2SL, the cell plug PL is protected.

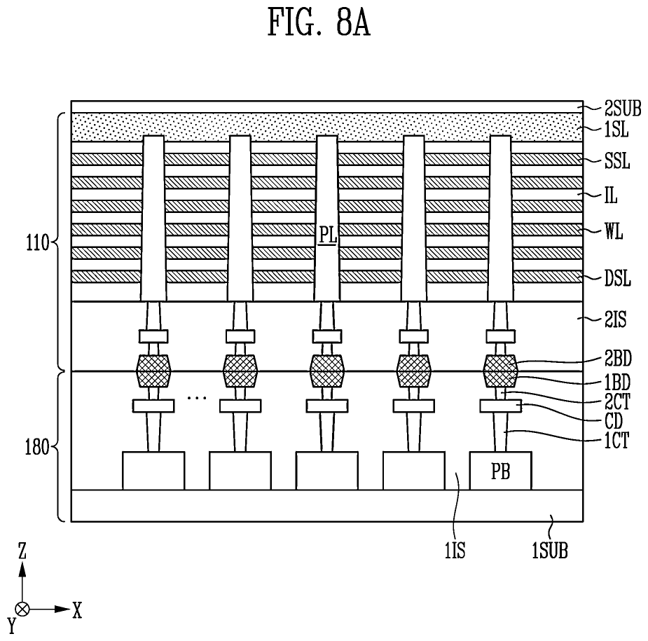

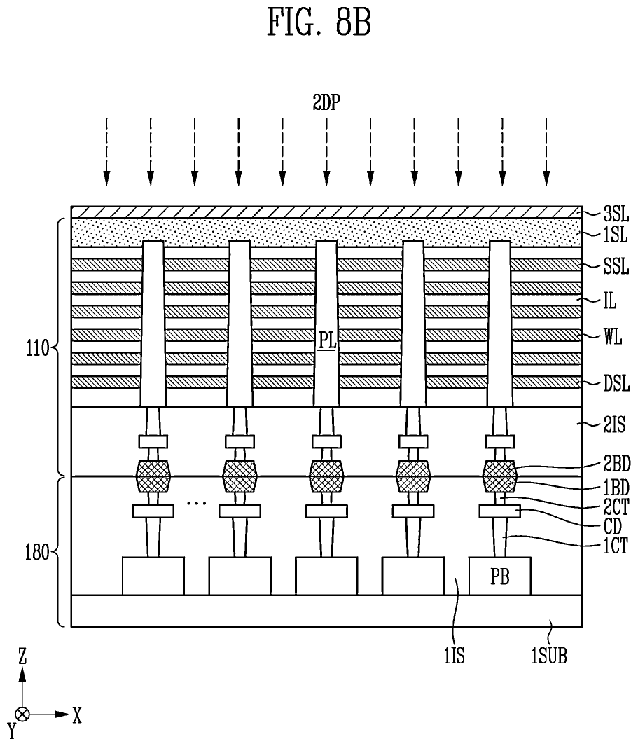

FIG. 8A and FIG. 8B are cross-sectional views of a memory device formed utilizing a method of manufacturing the memory device according to an embodiment of the present disclosure.

Referring to FIG. 8A, in the process described with reference to FIG. 6E, the second substrate 2SUB is not completely removed and a section or plane of the second substrate 2SUB remains. As a result, some but not all of the second substrate 2SUB is removed, and the first source line 1SL is not exposed during removal of some of the second substrate 2SUB. A thickness of the remaining section of the second substrate 2SUB may be the same as a thickness of the second source line 2SL described with reference to FIG. 7. The etching process that removes the portion of the second substrate 2SUB may be performed utilizing a wet etching process, a planarization process, or a combination thereof.

Referring to FIG. 8B, a third source line 3SL may be formed by implanting second impurities 2DP into the second substrate 2SUB remaining over the first source line 1SL. For example, the second impurities 2DP may be the same as the first impurities 1DP described with reference to FIG. 6B or may include N-type impurities that are different from the first impurities 1DP. Because the second substrate 2SUB changes into an amorphous material after the second impurities 2DP are implanted, a heat treatment process may be performed to change the amorphous material into a crystalline material. The second substrate 2SUB into which the second impurities 2DP are injected forms the third source line 3SL by the heat treatment process.

In the third embodiment, because the cell plug PL is not exposed when forming the third source line 3SL, the cell plug PL is protected.

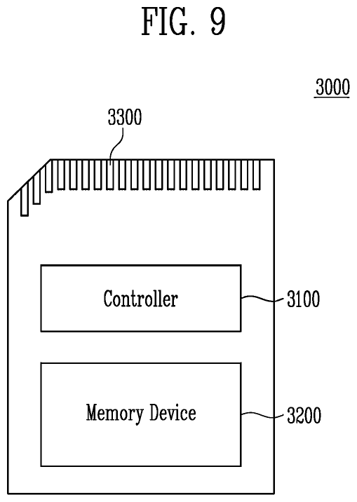

FIG. 9 is a diagram illustrating an embodiment of a memory card system 3000 including a memory device according to an embodiment of the present disclosure.

Referring to FIG. 9, the memory card system 3000 includes a controller 3100, a memory device 3200, and a connector 3300.

The controller 3100 is coupled to the memory device 3200. The controller 3100 is configured to access the memory device 3200. For example, the controller 3100 is configured to control a program operation, a read operation, an erase operation, and a background operation of the memory device 3200. The controller 3100 is configured to provide an interface between the memory device 3200 and a host. The controller 3100 is configured to run firmware that controls the memory device 3200. For example, the controller 3100 may include components such as a Random Access Memory (RAM), a processing unit, a host interface, a memory interface, and an error corrector.

The controller 3100 communicates with an external device through the connector 3300. The controller 3100 communicates with the external device, for example, a host, according to a specific communication protocol. For example, the controller 3100 may be configured to communicate with the external device through at least one of various communication protocols such as Universal Serial Bus (USB), Multi-Media Card (MMC), embedded MMC (eMMC), Peripheral Component Interconnection (PCI), PCI express (PCI-E), Advanced Technology Attachment (ATA), Serial-ATA (SATA), Parallel-ATA (PATA), Small Computer System Interface (SCSI), Enhanced Small Disk Interface (ESDI), Integrated Drive Electronics (IDE), Firewire, Universal Flash Storage (UFS), Wi-Fi, Bluetooth, and NVMe protocols. For example, the connector 3300 may be configured according to at least one of the above communication protocols.

The memory device 3200 may include a plurality of memory cells and may be configured, for example, in the same manner as the memory device 100 shown in FIG. 1. The memory device 3200 includes a memory cell array manufactured according to one or more of the manufacturing methods described with respect to FIG. 5, FIG. 6A through FIG. 6E, FIG. 7, and FIG. 8A and FIG. 8B.

The controller 3100 and the memory device 3200 are integrated into a single semiconductor device to form a memory card. For example, the controller 3100 and the memory device 3200 may form a memory card such as a personal computer (PC) card (Personal Computer Memory Card International Association (PCMCIA)), a Compact Flash (CF) card, a Smart Media Card (SM and SMC), a memory stick, a Multi-Media Card (MMC, RS-MMC, MMCmicro, or eMMC), an SD card (SD, miniSD, microSD, or SDHC), and a Universal Flash Storage (UFS).

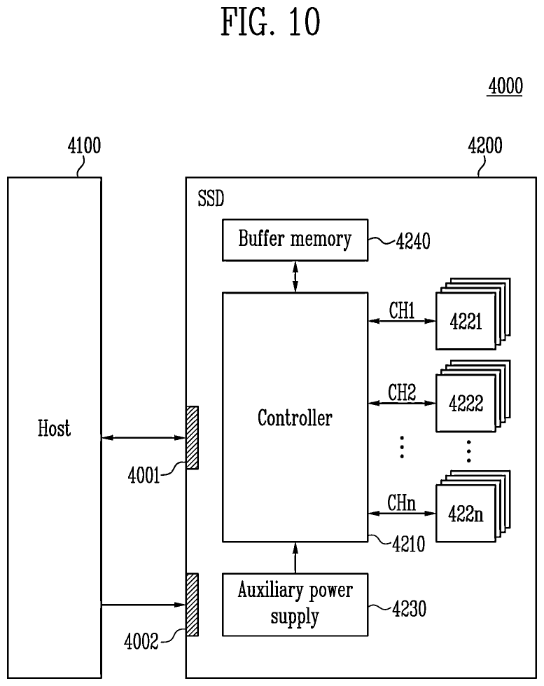

FIG. 10 is a diagram illustrating an embodiment of a solid state drive (SSD) system 4000 including a memory device according to an embodiment of the present disclosure.

Referring to FIG. 10, an SSD system 4000 includes a host 4100 and an SSD 4200. The SSD 4200 exchanges signals with the host 4100 through a signal connector 4001 and receives power through a power connector 4002. The SSD 4200 includes a controller 4210, a plurality of memory devices 4221 to 422n, an auxiliary power supply 4230, and a buffer memory 4240.

The controller 4210 controls the plurality of memory devices 4221 to 422n in response to signals received from the host 4100. For example, the signals may be a signals based on an interface between the host 4100 and the SSD 4200. For example, the signals may be configured or constructed according to at least one of a plurality of interfaces such as Universal Serial Bus (USB), Multi-Media Card (MMC), embedded MMC (eMMC), Peripheral Component Interconnection (PCI), PCI express (PCI-E), Advanced Technology Attachment (ATA), Serial-ATA (SATA), Parallel-ATA (PATA), Small Computer System Interface (SCSI), Enhanced Small Disk Interface (ESDI), an Integrated Drive Electronics (IDE), Firewire, Universal Flash Storage (UFS), WI-FI, Bluetooth, and NVMe interfaces.

Each of the plurality of memory devices 4221 to 422n includes a plurality of memory cells configured to store data. Each of the plurality of memory devices 4221 to 422n is configured, for example, in the same manner as the memory device 100 shown in FIG. 1. The plurality of memory devices 4221 to 422n communicates with the controller 4210 through channels CH1 to CHn. Each of the memory devices 4221 to 422n includes a memory cell array manufactured according to one or more of the manufacturing methods described with respect to FIG. 5, FIG. 6A through FIG. 6E, FIG. 7, and FIG. 8A and FIG. 8B.

The auxiliary power supply 4230 is coupled to the host 4100 through a power connector 4002. The auxiliary power supply 4230 receives power input from the host 4100 and may be charged. When the supply of power from the host 4100 is not smooth or consistent, the auxiliary power supply 4230 provides power to the SSD 4200. For example, the auxiliary power supply 4230 may be located inside or outside the SSD 4200. For example, the auxiliary power supply 4230 may be located on a main board and provide auxiliary power to the SSD 4200.

The buffer memory 4240 serves as a buffer memory of the SSD 4200. For example, the buffer memory 4240 temporarily stores data received from the host 4100 or data received from the plurality of memory devices 4221 to 422n, or temporarily stores metadata, for example, mapping tables, of the memory devices 4221 to 422n. The buffer memory 4240 may include one or more volatile memories such as DRAM, SDRAM, DDR SDRAM, and LPDDR SDRAM, or non-volatile memories such as FRAM, ReRAM, STT-MRAM, and PRAM.

According to embodiments of the present disclosure, warpage of a substrate may be reduced.

What is claimed is:

1. A method of manufacturing a memory device, the method comprising:
forming a peripheral circuit over a first substrate;
forming a first source line over a second substrate;
forming a memory cell array including gate lines, cell plugs extending through the gate lines, and bit lines electrically coupled to the cell plugs that protrude into the first source line;
bonding the memory cell array to the peripheral circuit; and
removing at least a portion of the second substrate.

2. The method of claim 1, wherein the forming the first source line comprises:
implanting first impurities into the second substrate; and
crystallizing an area where the first impurities are implanted.

3. The method of claim 2, wherein the first impurities include N-type impurities.

4. The method of claim 2, wherein the first impurities include phosphorus (P) ions or arsenic (As) ions.

5. The method of claim 2, wherein a heat treatment process is performed to crystallize the area where the first impurities are implanted.

6. The method of claim 1, wherein removing at least a portion of the second substrate is performed utilizing a wet etching process.

7. The method of claim 1, wherein removing at least a portion of the second substrate is performed by a chemical mechanical polishing (CMP) process.

8. The method of claim 1, wherein, a chemical mechanical polishing (CMP) process and a wet etching process are sequentially performed to remove at least a portion of the second substrate.

9. The method of claim 1, wherein forming the peripheral circuit comprises:
forming transistors and contacts over the first substrate; and
forming first bonding pads on outermost contacts among the contacts.

10. The method of claim 9, wherein the first bonding pads include copper (Cu).

11. The method of claim 1, wherein the forming the memory cell array comprises:
forming the gate lines and the cell plugs over the first source line;
forming the bit lines coupled to the cell plugs; and
forming second bonding pads coupled to the bit lines.

12. The method of claim 11, wherein the second bonding pads include copper (Cu).

13. The method of claim 1, further comprising, after removing the second substrate, forming a second source line over the first source line exposed by removing the second substrate.

14. The method of claim 13, wherein the second source line includes polysilicon (Poly-Si).

15. The method of claim 1, wherein removing at least a portion of the second substrate comprises:
leaving a section of the second substrate such that the first source line is not exposed; and
forming a third source line by implanting second impurities into the section of the second substrate.

16. The method of claim 15, wherein forming the third source line further comprises performing a heat treatment process to crystalize the section of the second substrate where the second impurities are implanted.

17. The method of claim 15, wherein the second impurities include N-type impurities.

18. The method of claim 1, further comprising flipping the memory cell array including the first source line such that the second substrate is located at an opposite end of the memory cell array than where the second substrate was located prior to flipping.

19. A method of manufacturing a memory device, the method comprising:
forming a peripheral circuit over a first substrate;
performing an ion implantation process on a second substrate;
forming a memory cell array over the ion-implanted second substrate;
bonding the memory cell array to the peripheral circuit; and
removing a portion of the second substrate.

20. The method of claim 19, wherein the ion implantation process comprises implanting N-type impurities into a portion of the second substrate.

21. The method of claim 19, wherein a section of the second substrate over which the ion implantation process is performed remains after removing the portion of the second substrate.

22. The method of claim 19, further comprising flipping the memory cell array such that the second substrate is located at an opposite end of the memory cell array than where the second substrate was located prior to flipping.

23. A method comprising:
forming a peripheral circuit over a first substrate;
implanting first impurities into a second substrate to form a first source line;
forming a memory cell array over the second substrate such that cell plugs of the memory cell array extend into the first source line;
bonding the memory cell array to the peripheral circuit; and
removing at least a portion of the second substrate.
